(19) United States
(12) Patent Application Publication
(10) Pub. No.: US 2021/0183803 A1
(43) Pub. Date: Jun. 17, 2021

(54) RECONSTRUCTED WAFER TO WAFER BONDING USING A PERMANENT BOND WITH LASER RELEASE

(71) Applicant: Micron Technology, Inc., Boise, ID (US)

(72) Inventor: Andrew M. Bayless, Boise, ID (US)

(21) Appl. No.: 16/718,068

(22) Filed: Dec. 17, 2019

(51) Int. Cl. H01L 23/00

(52) U.S. Cl. CPC H01L 24/29; H01L 24/83; H01L 2224/8313; H01L 2924/01008; H01L 2224/83224; H01L 2224/83005

(57) ABSTRACT

A non-elastic material layer is formed above a carrier wafer. An oxide layer is formed above the non-elastic material layer. Multiple integrated circuit die are bonded on the oxide layer using an oxide to oxide bond to form a reconstructed wafer.

### TECHNICAL FIELD

Embodiments of the disclosure relate generally to semiconductor fabrication, and more specifically, relate to wafer to wafer bonding.

### BACKGROUND

Integrated circuit (IC) die stacking can include a process of mounting multiple die above one another where the stacked die are eventually packaged in a single semiconductor package to form a discrete electrical device. The adoption of stacked IC die continues to increase in an effort to reduce the overall electrical device footprint and to improve the electrical performance of the electrical device.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates a fabrication process for performing wafer to wafer bonding including first operations for forming a non-elastic material layer and oxide layer on a carrier wafer, in accordance with some embodiments of the disclosure.

FIG. 1B illustrates a fabrication process for performing wafer to wafer bonding including second operations for forming alignment features, in accordance with some embodiments of the disclosure.

FIG. 2 illustrates a fabrication process for performing wafer to wafer bonding including third operations for bonding IC die to a carrier wafer, in accordance with some embodiments of the disclosure.

FIG. 3A-3B illustrates a fabrication process for performing wafer to wafer bonding including fourth operations for forming a dielectric layer above the IC die, in accordance with some embodiments of the disclosure.

FIG. 4 illustrates a fabrication process for performing wafer to wafer bonding including fifth operations for bonding a reconstructed wafer with another wafer, in accordance with some embodiments of the disclosure

FIG. 5 illustrates a fabrication process for performing wafer to wafer bonding including sixth operations for directing a laser source device through a carrier wafer, in accordance with some embodiments of the disclosure.

FIG. 6 illustrates a fabrication process for performing wafer to wafer bonding including seventh operations for removing a carrier wafer, in accordance with some embodiments of the disclosure.

FIG. 7 illustrates a fabrication process for performing wafer to wafer bonding including eighth operations for removing the non-elastic material layer and oxide layer, in accordance with some embodiments of the disclosure.

FIG. 8 illustrates a flow diagram of a fabrication process for wafer to wafer bonding, in accordance with some embodiments of the disclosure.

FIG. 9 is a computing device fabricated in accordance with embodiments of the disclosure.

### DETAILED DESCRIPTION

In some conventional fabrication systems, die stacking includes fabricating one or more wafers with IC die. The wafers are diced and the diced IC die are sorted to find functional “good” die and remove non-functional “bad” die. Two functional diced IC die are selected and mounted on top of one another. Stacking functional diced IC die produces high yields, but low throughput.

A non-reconstructed wafer can refer to a semiconductor wafer on which electronic circuits (e.g., multiple IC die) are directly fabricated. A reconstructed wafer can refer to a wafer having IC die that are attached to a substrate. The IC die of a reconstructed wafer can be IC die that have been previously fabricated on a non-reconstructed wafer, diced from the non-reconstructed wafer, and physically attached to a substrate of the reconstructed wafer.

In some conventional fabrication systems, die stacking includes fabricating IC die on at least two semiconductor wafers (e.g., non-reconstructed wafers). Without dicing the wafers, the two non-reconstructed wafers are bonded together such that IC die on a first non-reconstructed wafer are mounted on top of corresponding IC die on the second non-reconstructed wafer. Since each of the non-reconstructed wafers are likely to have non-functional die, non-reconstructed wafer to non-reconstructed wafer bonding results in numerous non-functional stacked die and ultimately low yields. When more than two non-reconstructed wafers are bonded, yield loss is further amplified.

In still other conventional systems, reconstructed wafers are created using diced IC die that are attached to substrates using polymer-based adhesives. The reconstructed wafers using adhesives can be bonded to another non-reconstructed wafer in a wafer to wafer bonding process. The adhesives used in reconstructive wafers can be elastic, non-rigid, non-uniformly distributed, and limited to low temperature or low force (e.g., pressure, lateral friction, etc.) fabrication operations. For example, during high temperature or high force fabrication operations the adhesive can deform such that the diced IC die adhering to the substrate move in one or more of the X-, Y-, or Z-direction. Due to the temperature constraints, movement, height variation (e.g., often due to non-uniform distribution or movement), and non-rigid surface wafer to wafer bonding using adhesive-based reconstructed wafers results in low yields.

Aspects of the disclosure address the above and other deficiencies by forming a reconstructed wafer that is rigid, non-elastic, uniformly distributed, and maintains the rigidity and non-elasticity during high temperature fabrication processes (e.g., copper to copper bonding or oxide to oxide fusion bonding) and high force fabrication processes (e.g., chemical mechanical planarization).

In some embodiments, a non-elastic material layer is formed above a carrier wafer. A carrier wafer can refer to a non-patterned wafer that is not patterned with electrical circuits (e.g., IC die) at any point during a fabrication process. In an example, the non-elastic material layer can include a metal layer or metal-alloy layer. An oxide layer can be formed above the non-elastic material layer. Multiple diced IC die can be bonded to the oxide layer using an oxide to oxide bond to form a reconstructed wafer. In some embodiments, a non-elastic material can deform when a force is applied to the material but does not return to its initial shape or size when the force is removed (e.g., permanent deformation). In some embodiments, the non-elastic material can have a modulus of elasticity of greater than or equal to 60 gigapascals (GPa). In some embodiments, the non-elastic material can have an elastic limit of 14 kilo-pounds per square inch (ksi) or greater. In some instances, a non-elastic material can have a high elastic modulus and low elastic limit.

In some embodiments, another non-reconstructed wafer or reconstructed wafer can be bonded to the reconstructed wafer. In some embodiments, a laser source device can be directed to emit light that passes through the carrier wafer in a direction from a first surface of the carrier wafer to a second surface of the carrier wafer where the emitted light contacts the adjacent surface of the non-elastic material layer. In some embodiments, the emitted light can degrade the bond between the carrier wafer and the non-elastic material layer and enable a de-bonding between the carrier wafer and non-elastic material layer. In some embodiments, the non-elastic material layer can help shield the bonded IC die from one or more of electromagnetic radiation and thermal radiation, which protects the bonded IC die from damage.

In some embodiments, the carrier wafer is removed from the non-elastic material layer based in at least part from degradation of the bond between the carrier wafer and non-elastic material layer cause by the emitted light. The non-elastic material layer and oxide layer can be removed by fabrication processes that expose the underlying stacked IC die. Further stacking of IC die can be performed by repeating similar operations, or the stacked die can be diced and packaged in semiconductor packaging.

Advantages of the disclosure include, but are not limited to, improved IC die yield in view of other wafer to wafer bonding techniques, improved throughput, and an improved reconstructed wafer that can be used in high temperature and high force semiconductor fabrication operations to produce high yield stacked IC die.

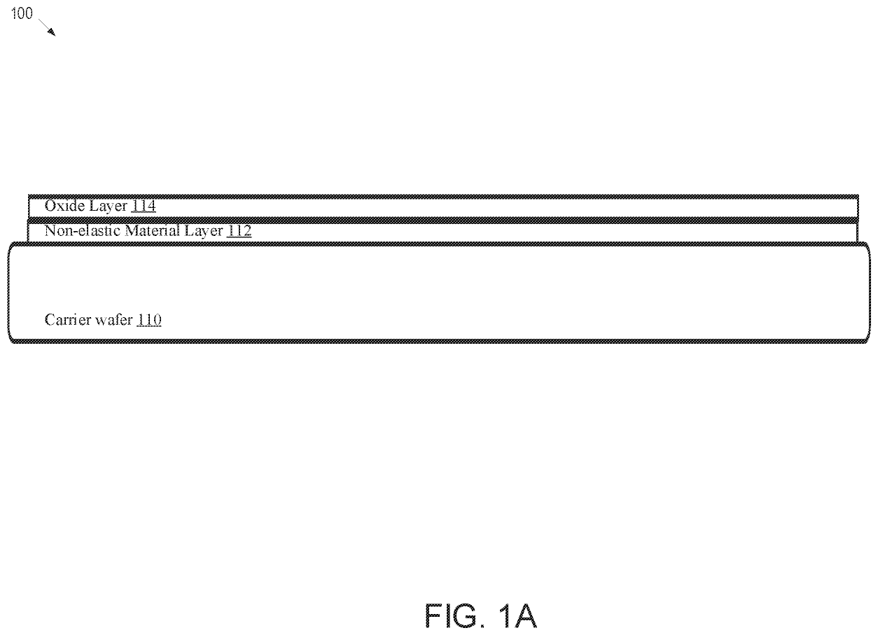

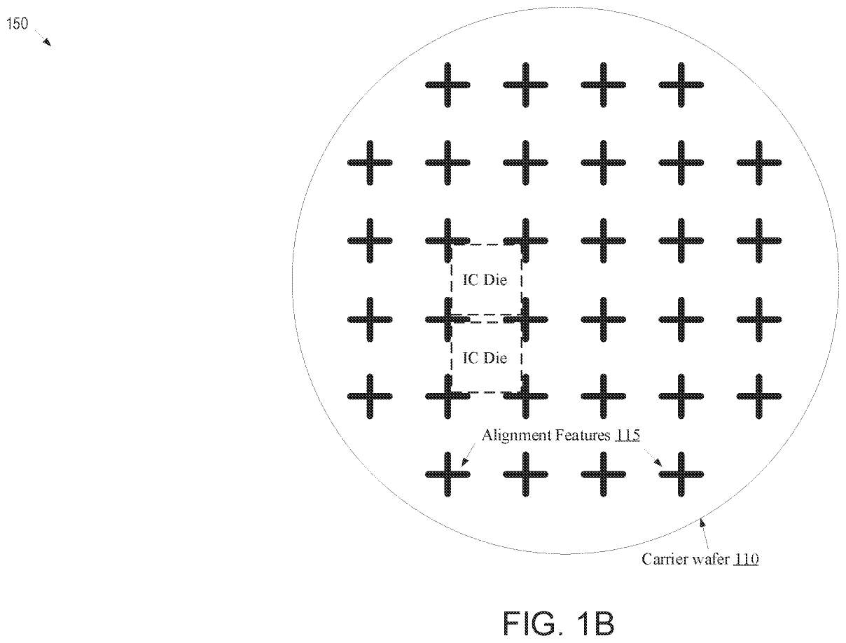

It can be noted that the following FIGS. 1A-7 are described as a series of operations for purposes of illustration, rather than limitation. It can be noted that some, all, more, or different operations can be performed in some embodiments. It can be noted that in some embodiments, some of the operations can be performed in a different order or not at all.

FIG. 1A illustrates a fabrication process for performing wafer to wafer bonding including first operations for forming a non-elastic material layer and oxide layer on a carrier wafer, in accordance with some embodiments of the disclosure.

Operation 100 of FIG. 1A illustrates a carrier wafer 110 (also referred to as a “temporary carrier wafer” herein). As described above, a carrier wafer can refer to a non-patterned wafer that is not patterned with electrical circuits at any point during a fabrication process. In some embodiments, a carrier wafer 110 can be distinguished from a device wafer, which is patterned during a semiconductor fabrication process with electrical circuits. A carrier wafer 110 can be used as a handling tool on which a device wafer or in some embodiments, pre-fabricated IC die, can be temporarily bonded. In some embodiments, the carrier wafer 110 is fully removed from the associated IC die at some point during the fabrication process and before the IC die are diced or packaged in discrete semiconductor packaging.

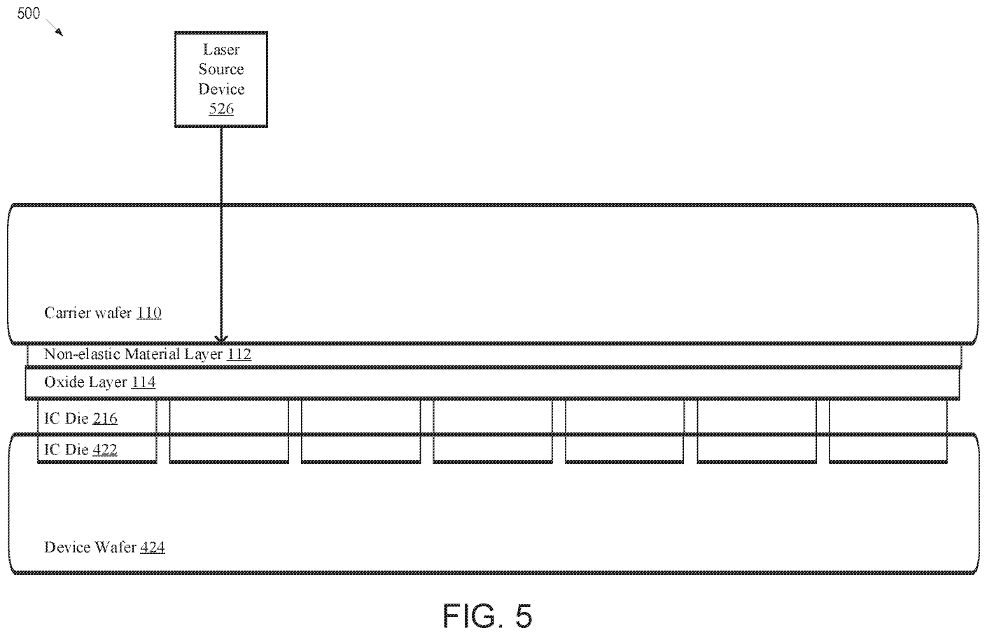

In some embodiments, the carrier wafer 110 can include a material that allow some wavelength of light (e.g., laser) to pass through the carrier wafer 110. For example, the carrier wafer 110 can be a circular shape with two planar sides and an edge area. The light can pass from the first planar side through the second planar side. In some embodiments, the carrier wafer 110 can include silicon and allow infrared radiation (IR) (700 nanometers (nm) to 1 millimeter (mm) wavelength) to pass through the carrier wafer 110. In some embodiments, the carrier wafer can include glass and allow ultraviolet radiation (UV) (10 nm to 400 nm wavelength) to pass through the carrier wafer 110. A laser source device 526 that emits a wavelength of light through the carrier wafer 110 is further described with respect to FIG. 5.

In some embodiments, the carrier wafer 110 can include one or more of the following materials, including but not limited to, glass, silicon quartz, gallium arsenide, indium phosphide, silicon carbide.

In some embodiments, the non-elastic material layer 112 can be formed above the carrier wafer 110. In some embodiments, the non-elastic material layer 112 can be formed directly on the carrier wafer 110 where a surface of the carrier wafer 110 contacts a corresponding surface of the non-elastic material layer 112. In some embodiment, the non-elastic material layer 112 can be a single layer or a stack of multiple layers (e.g., stack of one or more non-elastic materials).

In some embodiments, the non-elastic material layer 112 can absorb or block the wavelength of light that penetrates the carrier wafer 110. The non-elastic material layer 112 can block the wavelength of light from penetrating a subsequent layer, such as oxide layer 114. By blocking the wavelength of light, the non-elastic material layer 112 prevents the light (e.g., electromagnetic radiation) from damaging the IC die that are to be bonded above the carrier wafer 110. For example, the non-elastic material layer 112 can block IR or UV light emitted from the laser source device. In some embodiments, the non-elastic material layer 112 can also degrade or release from the carrier wafer 110 (at least in part) responsive to exposure from the emitted light that is directed to pass through the carrier wafer 110. In some embodiments, the non-elastic material layer 112 can also absorb, block, or disperse at least some of the thermal energy created by the emitted light, which can help prevent damage to the bonded IC die.

In some embodiments, the non-elastic material layer 112 can be processed at high temperatures (e.g., above 250-300 degrees Celsius) and not degrade or deform. In some embodiments, the non-elastic material layer 112 is a rigid material. In some embodiments, the non-elastic material layer 112 can be a continuous film (without holes) formed across a planar surface of the carrier wafer 110. In some embodiments, the non-elastic material layer 112 can range in thickness from 1,000-1,500 Angstroms. In some embodiments, the non-elastic material layer 112 can be thinker than 1,500 Angstroms.

In some embodiments, the non-elastic material layer 112 can be formed by a deposition operation, such as a physical vapor deposition operation, that deposits the non-elastic material layer 112 above the carrier wafer 110. In embodiments, the non-elastic material layer 112 can include, but is not limited to, materials such as Titanium, Tantalum, Copper, Rubidium, Cobalt, Nickel, Iron, Silicon, Germanium, Aluminum or alloys, nitrides, or oxides of the materials. In some embodiments, the non-elastic material layer 112 can be a composite material. In some embodiments, the non-elastic material layer 112 is a metal layer or metal-alloy layer. In some embodiments, the non-elastic material layer can include one or more layers of materials (e.g., sub-layers or stack of materials).

In some embodiments, an oxide layer 114 can be formed above the non-elastic material layer 112. In some embodiments, the oxide layer 114 can be formed directly on the non-elastic material layer 112. In some embodiments, the oxide layer 114 can be an oxide of the underlying non-elastic material layer 112 (e.g., grown on the non-elastic material layer 112). In some embodiments, the oxide layer can be an oxide of another material that is different from the underlying non-elastic material layer 112 (e.g., deposited on the non-elastic material layer 112). In some embodiments, the oxide layer 114 can be formed by a deposition operation such as chemical bath deposition (CBD) operation or photo chemical bath deposition (PCBD) operation. In some embodiments, the oxide layer 114 can be formed by different operations.

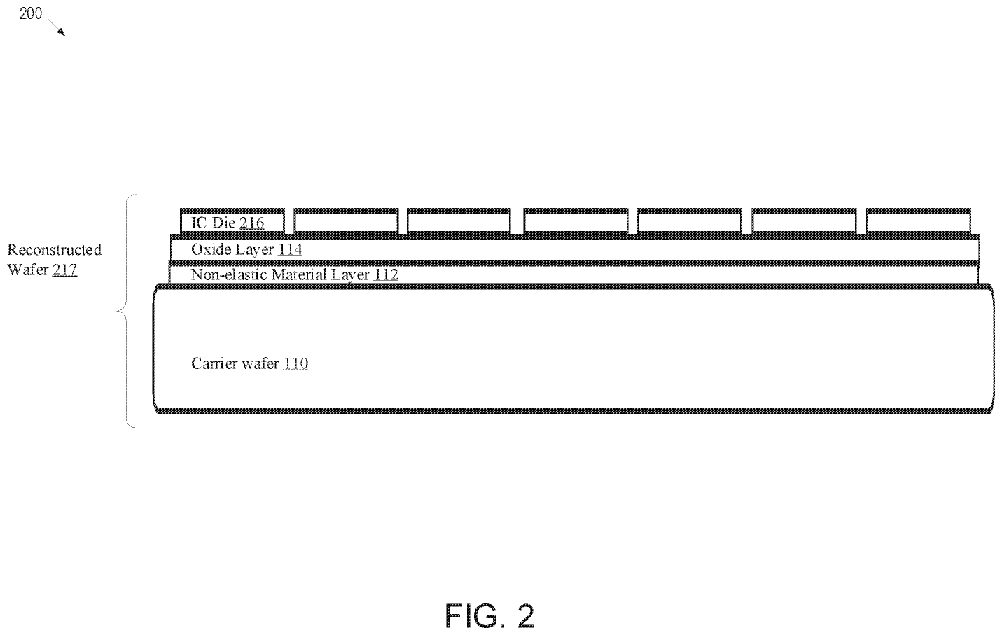

In some embodiments, the oxide layer 114 can have a requisite thickness to act as a thermal barrier that protects the IC dies (e.g., IC die 216 of FIG. 2) bonded to the oxide layer 114 from heat generated from the emitted light (e.g., via the laser source device 526) that travels through the carrier wafer 110 and contacts a side of the non-elastic material layer 112 adjacent to the carrier wafer 110. In some embodiments, the oxide layer 114 can have an additional thickness to compensate for any planarization operation performed on the oxide layer 114 after formation. In some embodiments, the oxide layer 114 can have a thickness between 1,000 and 5,000 Angstroms. In some embodiments, the oxide layer 114 can have a thickness of greater than 5,000 Angstroms. In some embodiments, the oxide layer 114 can be formed by a deposition operation, rather than a growth operation, to efficiently achieve the desired thickness.

In some embodiment, subsequent to forming the oxide layer 114, the oxide layer 114 can be smoothed by a planarization operation (e.g., polishing operation), such as a chemical mechanical planarization (CMP) operation.

FIG. 1B illustrates a fabrication process for performing wafer to wafer bonding including second operations for forming alignment features, in accordance with some embodiments of the disclosure.

Operation 150 illustrates alignment features 115 that are formed above the carrier wafer 110. In some embodiments, the alignment feature 115 can identify locations where the IC die 216 are to be bonded to the oxide layer 114. In some embodiments, the alignment features 115 can be formed in “streets” that are areas positioned between the IC die 216 that are bonded to the oxide layer 114. As illustrated in FIG. 1B, the alignment features 115 are positioned in the streets and identify where the IC die 216 are to be positioned within the square formed by the alignment features 115.

In some embodiments, the alignment features 115 can be formed on the non-elastic material layer 112 or the oxide layer 114. For example, the non-elastic material layer 112 can be etched in a particular pattern of the alignment features 115 and the oxide layer 114 can be formed above the alignment features 115 of the non-elastic material layer 112. A charged coupled device (CCD) can be used to detect the alignment features 115 under the oxide layer 114. In another example, the alignment features 115 can be etched into the top surface of the oxide layer 114 and an optical camera (or CCD) can be used to detect the alignment features 115 on the oxide layer 114.

FIG. 2 illustrates a fabrication process for performing wafer to wafer bonding including third operations for bonding IC die above a carrier wafer, in accordance with some embodiments of the disclosure.

In some embodiments, the IC die 216 are diced from a non-reconstructed wafer, such as a device wafer, and selected for placement on the carrier wafer. For example, the IC die 216 can be diced from one or more device wafers and sorted to identify functional IC die (e.g., tested for functionality). Non-functional IC die can be removed from the group, while the functional IC die are kept in the group that are to be bonded to the oxide layer 114.

In operation 200, multiple IC die 216 (e.g., sorted functional IC die) are bonded to the oxide layer 114 using an oxide to oxide bond. In embodiments, the oxide to oxide bond is a rigid and strong bond that can withstand fabrication processes that involve high temperature or high force without displacement of the IC die 216. It can be noted that the IC die 216 can have an oxide layer on a surface (e.g., bottom surface) of the IC die 216 prior to performing the bonding operation with the oxide layer 114. In some embodiments, an oxide to oxide bond can be created by an oxide to oxide fusion bonding operation. In an oxide to oxide fusion bonding operation the IC die can be aligned on the oxide layer 114 at room temperature. The oxide layer 114 and the oxide of the IC die 216 form a Van der Walls bond at room temperature (e.g., oxygen and hydrogen bond). The carrier wafer 110 that includes the non-elastic material layer 112, oxide layer 114, and IC die 216 can be heated, which diffuses the hydrogen into the oxide and out of the oxygen and hydrogen bond to form an oxide to oxide bond.

In some embodiments, carrier wafer 110 that includes the bonded IC die 216 form a reconstructed wafer 217.

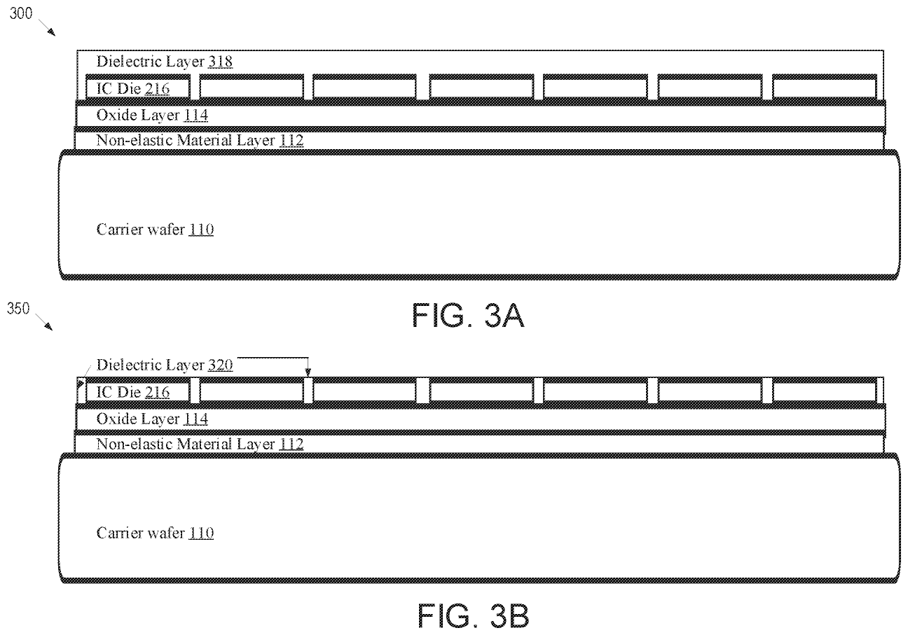

FIG. 3A-3B illustrates a fabrication process for performing wafer to wafer bonding including fourth operations for forming a dielectric layer above the IC die, in accordance with some embodiments of the disclosure.

At operation 300 in FIG. 3A, a dielectric layer 318 is formed above the IC die 216. In some embodiments, the dielectric layer is formed in the areas adjacent and in between the IC die 216 (e.g., streets). It can be noted that at number of fabrication processes can be performed subsequent to bonding the IC die 216 to the oxide layer 114 due at least in part to the rigid and strong oxide to oxide bond. Forming a dielectric layer 318 is an illustrative example of one such process. In other embodiments, additional of different fabrication processes can be performed.

In some embodiments, the dielectric layer 318 can be formed using a spin coating operation where a dielectric (e.g., polymer solution) is dispensed onto the surface of the reconstructed wafer 217 using rotational motion (e.g., spin). In other embodiments, any number of deposition techniques can be used including, but not limited to, a plasma deposition operation.

Representative dielectric materials may include, but are not limited to, various Oxides, Nitrides and Carbides, for example, Silicon Oxide, Titanium Oxide, Hafnium Oxide, Aluminum Oxide, Oxynitride, Zirconium Oxide, Hafnium Silicate, Lanthanum Oxide, Silicon Nitride, Boron Nitride, Amorphous Carbon, Silicon Carbide, Amorphous Silicon, Polymeric or other similar dielectric materials.

At operation 350 in FIG. 3B, a planarization operation is performed on dielectric layer 318 which leaves dielectric layer 320 in the area (e.g., streets) between the IC die 216. In some embodiments, the planarization operation can include a CMP operation. It can be noted that providing dielectric layer 318 and 320 can be optional operations based on the type of wafer to wafer bonding that is to be performed. In some types of wafer to wafer bonding, a dielectric material in the area between the IC die 216 is preferred. For example, in three dimensional (3D) memory devices, such as 3D NAND devices, spaces between IC die 216 may be undesirable and a dielectric layer 320 can be used to fill in the area between the IC die 216. A hybrid fusion bond (further described below) can be performed after the planarization operation is performed on the dielectric layer 318. Other types of wafer to wafer bonding can be performed without a dielectric material between the IC die 216. For example, in copper to copper bonding, such as TSV (described below), two wafers can be bonded together without filling in the areas between the IC die 216.

In some embodiments, a planarization operation can be performed after the IC die 216 are bonded to the oxide layer 114 and without the formation of the dielectric layer 318. For example, the IC die 216 can be polished to expose electrical contacts such as through-silicon vias (TSV). TSV can refer to vertical electrical connections that pass partly, or more often completely through a wafer or die. For example, multiple memory IC die can be stacked on top of one another and TSVs can pass through a first memory IC to connect a second memory IC stacked above the first memory IC to an underlying component, such as a controller die.

In some embodiments, the planarization operation can also serve to clean a reconstructed wafer 217 and prepare the reconstructed wafer 217 for one or more subsequent operations.

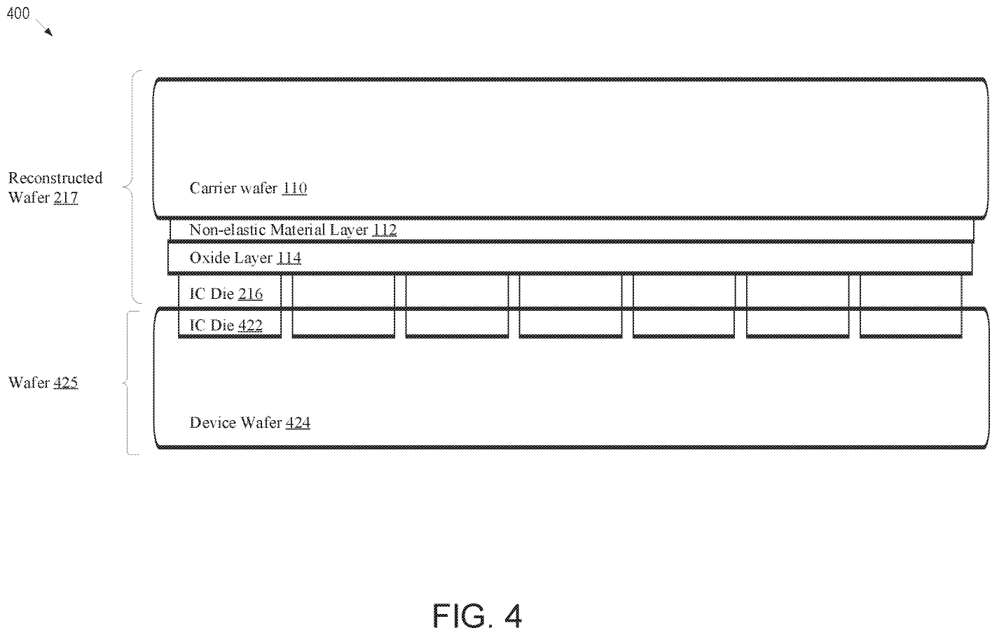

It can be noted that for purposes of illustration, rather than limitation, the reconstructed wafer shown in FIGS. 4-7 are illustrated without dielectric layer 320. In other embodiments, the operations illustrated with respect to FIGS. 4-7 can be performed with dielectric layer 320.

FIG. 4 illustrates a fabrication process for performing wafer to wafer bonding including fifth operations for bonding a reconstructed wafer with another wafer, in accordance with some embodiments of the disclosure. It can be noted that reconstructed wafer 217 as illustrated in FIG. 2 has been rotated 180 degrees for purposes of illustration.

Operation 400 illustrates wafer to wafer bonding where the reconstructed wafer 217 is bonded to another wafer, such as wafer 425. In some embodiments, wafer 425 can be another reconstructed wafer or a non-reconstructed wafer. In operation 400, wafer 425 is shown as a non-reconstructed wafer for purposes of illustration rather than limitation. In other embodiments, operation 400 (and subsequent operations described herein) can be performed on wafer 425 that is a reconstructed wafer. Wafer 425 includes device wafer 424 that has multiple IC die 422 that have been fabricated on the device wafer 424. For purpose of clarity, device wafer 424 can refer to the IC die 422 and the underlying wafer on which the IC die 422 have been fabricated. Device wafer 424 can be an example of a non-reconstructed wafer.

In some embodiments, the bond between the reconstructed wafer 217 and wafer 425 can be a copper to copper bond (e.g., may not have a dielectric layer 320 between the IC die 216) or a hybrid fusion bond, among other types of bonds.

In a copper to copper bonding operation, copper contacts (e.g., TSVs) are exposed on surfaces of IC die 216 and on corresponding surfaces of IC die 422. Reconstructed wafer 217 and wafer 425 are positioned such that the copper contacts of the IC die 216 contact corresponding copper contacts of IC die 422. The temperature can be increased to promote diffusion between the copper contacts of the IC die 216 and IC die 422.

In a hybrid fusion bonding operation, an oxide to oxide fusion bond is created followed by a copper to copper bond. For example, the copper interconnects (e.g., TSVs) can be exposed at surfaces of IC die 216 of the reconstructed wafer 217 and surfaces of IC die 422 of wafer 425. On areas of the surfaces of the IC die 216 and IC die 422 without TSVs can be other areas having an oxide layer. In the aforementioned oxide areas, oxide to oxide fusion bonding can be performed first to form an oxide to oxide bond between IC die 216 and IC die 422. The initial oxide to oxide bond can occur at room temperature, and the oxide to oxide bond can be further strengthened using an annealing operation (e.g., raising temperature to 150-200 degrees Celsius). The copper to copper bond then can be formed as the oxide to oxide bond holds the reconstructed wafer 217 and wafer 425 together. The copper to copper bonding can be performed as described herein. For example, the copper to copper bond can be created by further annealing at higher temperatures (e.g., greater than 325 degrees Celsius).

FIG. 5 illustrates a fabrication process for performing wafer to wafer bonding including sixth operations for directed a laser source device through a carrier wafer, in accordance with some embodiments of the disclosure.

Operation 500 illustrates directing laser source device 526 to emit a light of a selected wavelength that passes through the carrier wafer 110 in the direction from a first surface (e.g., top planar surface of the carrier wafer 110 as illustrated) of the carrier wafer 110 to a second surface (e.g., bottom planar surface of the carrier wafer 110 as illustrated) of the carrier wafer 110. As described herein, the wavelength of light is selected based on the material of the carrier wafer 110 so that the emitted light passes though the carrier wafer 110, contacts the adjacent surface of the non-elastic material layer 112 (e.g., top surface as illustrated), and degrades the bond between the carrier wafer 110 and non-elastic material layer 112.

In some embodiments, the emitted light degrades the bond between the carrier wafer 110 and the non-elastic material layer 112. In some embodiments, the non-elastic material layer 112 is a material that absorbs the emitted light and helps shield (both electromagnetic shielding and thermal shielding) IC die 216 (and IC die 422) from the emitted light to prevent damage to the IC die 216 and IC die 422. In some embodiments, the thickness of the oxide layer 114 can also be formed to a thickness to further contribute to thermal shielding and help dissipate thermal energy before damaging IC die 216 and IC die 422.

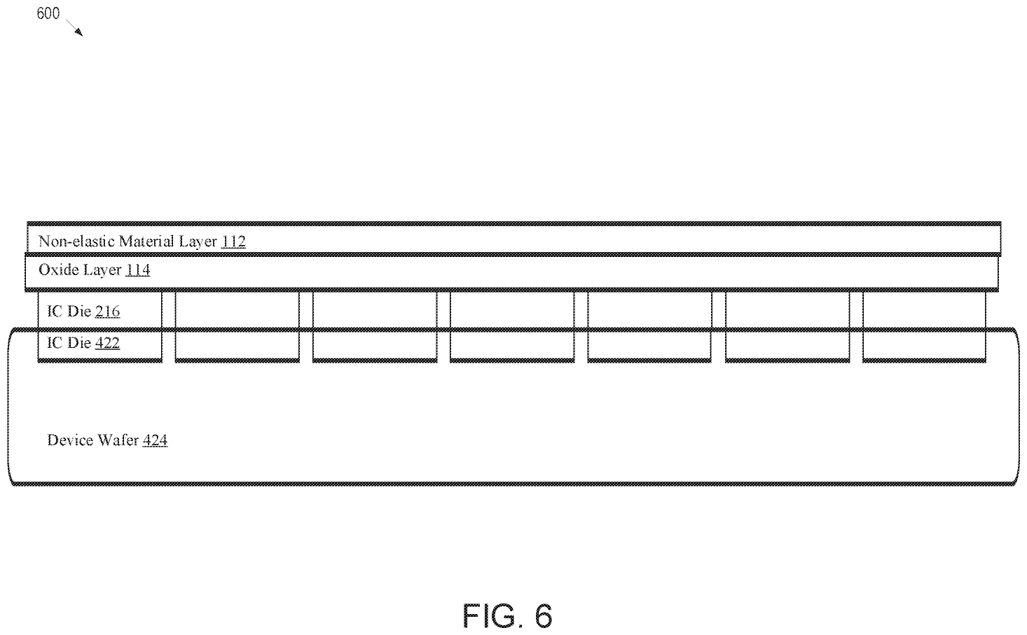

FIG. 6 illustrates a fabrication process for performing wafer to wafer bonding including seventh operations for removing a carrier wafer, in accordance with some embodiments of the disclosure.

Operation 600 illustrates the removal of the carrier wafer 110 from the underlying stack-up. In some embodiments, directing the laser source device 526 to emit light through the carrier wafer degrades the bond (e.g., de-bonding) between the carrier wafer 110 and non-elastic material layer 112 to a degree that the carrier wafer 110 can be mechanically removed by little to no applied force. In other embodiments, the other operations can be performed to remove the carrier wafer 110. For example, the carrier wafer 110 can be removed using a vacuum or side grip to lift off the carrier wafer 110.

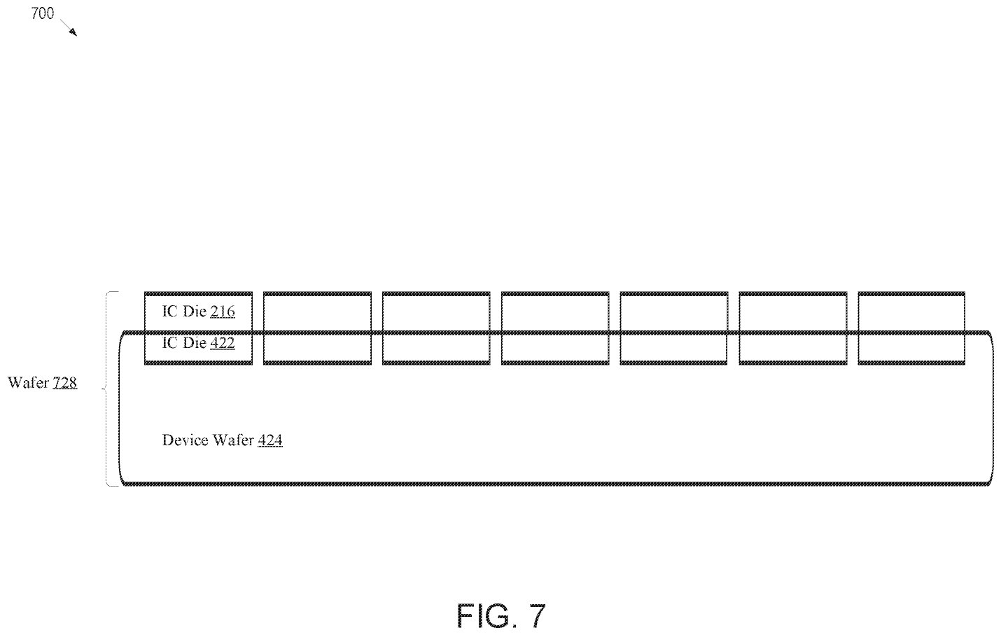

FIG. 7 illustrates a fabrication process for performing wafer to wafer bonding including eighth operations for removing the non-elastic material layer and oxide layer, in accordance with some embodiments of the disclosure.

Operation 700 shows the non-elastic material layer 112 and oxide layer 114 removed leaving the wafer 728 that includes device wafer 424 with stacked die, IC die 216 and IC die 422. In some embodiments, the non-elastic material layer 112 can be removed using one or more etch operations, such as a wet or dry etch. In some embodiments, the oxide layer 114 can also be removed using one or more etch operations, such as a dry or wet etch, or using planarization operations such as CMP operations.

In some embodiments, wafer 728 can be diced into multiple IC devices where each IC device includes stacked IC die including IC die 216 and IC die 422. In other embodiments, wafer 728 can undergo further operations to stack additional IC die or other device (e.g. interposer) above IC die 216. In some embodiments, another non-reconstructed wafer can be bonded to wafer 728 using similar operations as described herein. For example, the surface of wafer 728 can be further polished or a dielectric layer can be formed above IC die 216. An oxide to oxide bond can be formed between wafer 728 and the non-reconstructed wafer. In sill other embodiments, a reconstructed wafer can be bonded to wafer 728. The reconstructed wafer can be fabricated in a similar manner as described herein and include a carrier wafer, for instance. The reconstructed wafer can be bonded to wafer 728, and the carrier wafer, non-elastic material layer, and oxide layer of the reconstructed wafer can be removed in a similar manner as describe herein. The above operations can be performed repeatedly to fabricate stacked devices with the desired number and type of IC die.

In some embodiments, the wafer to wafer bonding can be used to create 3D NAND that stack multiple NAND die. The initial reconstructed wafer can include NAND die, and the wafer to wafer bonding can be between the reconstructed wafer and non-reconstructed wafer that includes additional NAND die. In another embodiment, the wafer to wafer bonding can be used to create a hybrid memory device that includes one or more dynamic random-access memory (DRAM) die that are stacked above a logic die, where all the die are stacked together using TSVs. An initial reconstructed wafer can include DRAM die, and the wafer to wafer bonding can be between the reconstructed wafer and a non-reconstructed wafer that includes logic die. Additional, DRAM can be stacked by bonding the resulting wafer (including the logic die and DRAM die) to another non-reconstructed wafer that includes additional DRAM die.

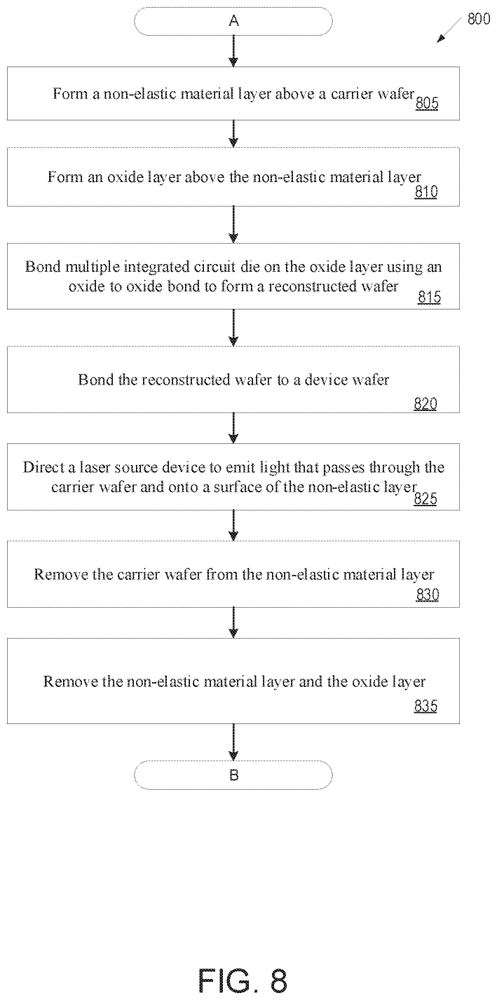

FIG. 8 illustrates a flow diagram of a fabrication process for wafer to wafer bonding, in accordance with some embodiments of the disclosure. Elements of FIGS. 1-7 may be described below to help illustrate method 800. Method 800 may be performed as one or more operations. It may be noted that method 800 may be performed in any order and may include the same, different, more, or fewer operations. It may be noted that method 800 may be performed by one or more pieces of semiconductor fabrication equipment or fabrication tools, herein after referred to as fabrication equipment.

At operation 805, fabrication equipment forms a non-elastic material layer above a carrier wafer. In some embodiments, the non-elastic material layer includes one or more of a metal layer or metal-alloy layer. In some embodiments, the non-elastic material layer is formed directly on the carrier wafer.

At operation 810, fabrication equipment forms an oxide layer above the non-elastic material layer. In some embodiments, the oxide layer is formed directly on the non-elastic material layer. In some embodiments, fabrication equipment forms alignment features above the carrier wafer. The alignment features can identify locations where the multiple integrated circuit die are to be bonded to the oxide layer.

At operation 815, fabrication equipment bonds multiple integrated circuit die on the oxide layer using an oxide to oxide bond to form a reconstructed wafer. In some embodiments, fabrication equipment forms a dielectric layer above the multiple integrated circuit die. Fabrication equipment performs a planarization operation to remove at least a portion of the dielectric layer and expose surfaces of the multiple integrated circuit die. In some embodiments, the oxide to oxide bond is formed using an oxide to oxide fusion bonding operation. In some embodiment, the carrier wafer is a temporary wafer that is removed prior to dicing the integrated circuit die.

At operation 820, fabrication equipment bonds the reconstructed wafer to a device wafer. The device wafer can include a second multiple (e.g., multitude) of integrated circuit die. The multiple integrated circuit die of the reconstructed wafer are bonded to respective die of the second multiple of integrated circuit die of the device wafer.

At operation 825, fabrication equipment directs a laser source device to emit light that passes through the carrier wafer. The emitted light passes through the carrier wafer in a direction from a first surface of the carrier wafer to a second surface of the carrier wafer. The emitted light is directed to contact a first surface of the non-elastic material layer that is adjacent to the carrier wafer. In some embodiments, the non-elastic material layer absorbs the emitted light and prevents the emitted light from passing to the oxide layer.

At operation 830, fabrication equipment removes the carrier wafer from the non-elastic material layer. The removal can be based in at least part by directing the laser source device to emit light that passes through the carrier wafer.

At operation 835, fabrication equipment removes the non-elastic material layer and the oxide layer.

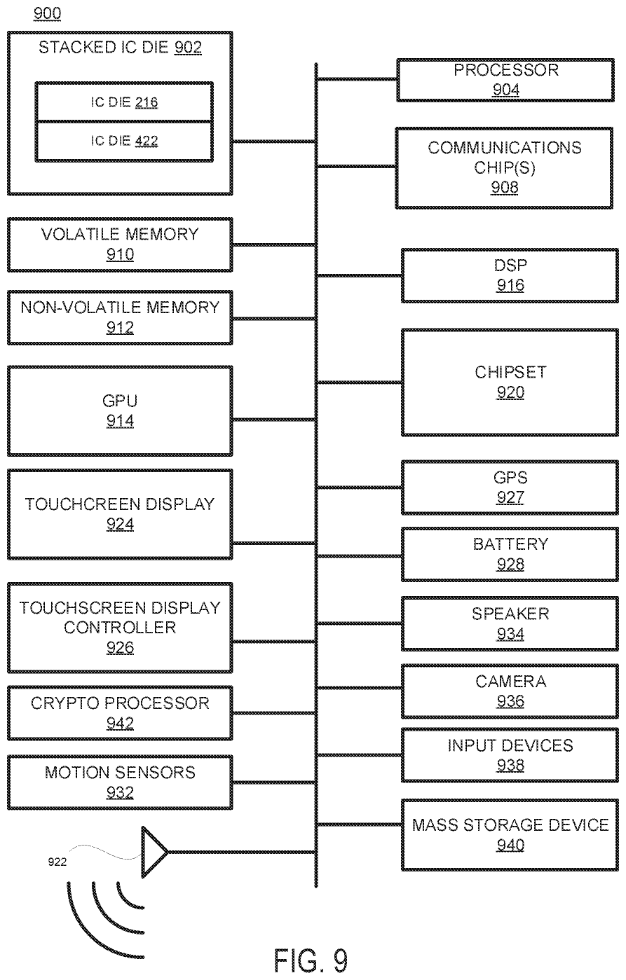

FIG. 9 is a computing device fabricated in accordance with embodiments of the disclosure. The computing device 900 may include a number of components. In one embodiment, the components are attached to one or more motherboards. In an alternate embodiment, some or all of these components are fabricated onto a single system-on-a-chip (SoC) die, such as an SoC used for mobile devices. In embodiments, the components in the computing device 900 include, but are not limited to, a stacked IC die 902 and at least one communications logic unit 908. In some embodiments, the communications logic unit 908 is fabricated in a separate integrated circuit chip that may be bonded to a substrate or motherboard that is shared with or electrically coupled to the stacked IC die 902. The stacked IC die 902 may include an IC die 216 bonded to another element, such as IC die 422. It may be noted that in embodiments stacked IC die 902 may include additional elements (e.g., additional IC die on the stacked die, a processor, etc.). In another example, stacked IC die 902 may include some or all the elements described herein, as well as include additional elements.

Computing device 900 may include other components that may or may not be physically and electrically coupled to the motherboard or fabricated within an SoC die. These other components include, but are not limited to, volatile memory 910 (e.g., DRAM), non-volatile memory 912 (e.g., ROM or flash memory), a graphics processing unit 914 (GPU), a digital signal processor 916, a crypto processor 942 (e.g., a specialized processor that executes cryptographic algorithms within hardware), a chipset 920, at least one antenna 922 (in some embodiments two or more antenna may be used), a display or a touchscreen display 924 (e.g., that may include stacked IC die 902), a touchscreen controller 926, a battery 928 or other power source, a power amplifier (not shown), a voltage regulator (not shown), a global positioning system (GPS) device 927, a compass (not shown), a motion coprocessor or sensors 932 (that may include an accelerometer, a gyroscope, and a compass), a microphone (not shown), a speaker 934, a camera 936, user input devices 938 (such as a keyboard, mouse, stylus, and touchpad), and a mass storage device 940 (such as hard disk drive, compact disk (CD), digital versatile disk (DVD), and so forth). The computing device 900 may incorporate further transmission, telecommunication, or radio functionality not already described herein. In some embodiments, the computing device 900 includes a radio that is used to communicate over a distance by modulating and radiating electromagnetic waves in air or space. In further embodiments, the computing device 900 includes a transmitter and a receiver (or a transceiver) that is used to communicate over a distance by modulating and radiating electromagnetic waves in air or space.

The communications logic unit 908 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 908 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 900 may include a multitude of communications logic units 908. For instance, a first communications logic unit 908 may be dedicated to shorter range wireless communications such as Wi-Fi, NFC, and Bluetooth and a second communications logic unit 908 may be dedicated to longer range wireless communications such as GPS, EDGE, GPRS, CDMA, WiMAX, LTE, Ev-DO, and others.

The processor 904 (also referred to “processing device” herein) may refer to any device or portion of a device that processes electronic data from registers and/or memory to transform that electronic data into other electronic data that may be stored in registers and/or memory. Processor 904 represents one or more general-purpose processing devices such as a microprocessor, a central processing unit, or the like. More particularly, the processor 904 may be complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 904 may also be one or more special-purpose processing devices such as an application specific integrated circuit (ASIC), a field programmable gate array (FPGA), a digital signal processor (DSP), network processor, or the like.

In various embodiments, the computing device 900 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further embodiments, the computing device 900 may be any other electronic device that processes data.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms or operations presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the disclosure is not described with reference to any particular programming language. It will be appreciated that a variety of programming languages can be used to implement the teachings of the disclosure as described herein.

The disclosure can be provided as a computer program product, or software, that can include a machine-readable medium having stored thereon instructions, which can be used to program a computer system (or other electronic devices) to perform a process according to the disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims may generally be construed to mean “one or more” unless specified otherwise or clear from context to be directed to a singular form. Moreover, use of the term “an embodiment” or “one embodiment” or “an implementation” or “one implementation” or the like throughout may or may not mean the same embodiment or implementation. One or more embodiments or implementations described herein may be combined in a particular embodiment or implementation. The terms “first,” “second,” “third,” “fourth,” etc. as used herein are meant as labels to distinguish among different elements and may not necessarily have an ordinal meaning according to their numerical designation.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
forming a non-elastic material layer above a carrier wafer;
forming an oxide layer above the non-elastic material layer; and
bonding a plurality of integrated circuit die on the oxide layer using an oxide to oxide bond to form a reconstructed wafer.

2. The method of claim 1, wherein the plurality of integrated circuit die are a first plurality of integrated circuit die, the method further comprising:
bonding the reconstructed wafer to a device wafer comprising a second plurality of integrated circuit die, wherein the first plurality of integrated circuit die of the reconstructed wafer are bonded to respective die of the second plurality of integrated circuit die of the device wafer.

3. The method of claim 2, further comprising:
directing a laser source device to emit light that passes through the carrier wafer in a direction from a first surface of the carrier wafer to a second surface of the carrier wafer, the light directed to contact a first surface of the non-elastic material layer.

4. The method of claim 3, further comprising:
removing the carrier wafer from the non-elastic material layer based in at least part by directing the laser source device to emit light that passes through the carrier wafer; and
removing the non-elastic material layer and the oxide layer.

5. The method of claim 1, wherein the non-elastic material layer comprises at least one of a metal layer or metal-alloy layer.

6. The method of claim 1, further comprising:
forming alignment features above the carrier wafer that identify locations where the plurality of integrated circuit die are to be bonded to the oxide layer.

7. The method of claim 1, further comprising:
forming a dielectric layer above the plurality of integrated circuit die; and
performing a planarization operation to remove at least a portion of the dielectric layer and expose surfaces of the plurality of integrated circuit die.

8. An apparatus, comprising:
a carrier wafer;
a non-elastic material layer disposed above the carrier wafer;
an oxide layer disposed above the non-elastic material layer; and
a plurality of integrated circuit die bonded to the oxide layer via an oxide to oxide bond.

9. The apparatus of claim 8, further comprising:
a dielectric layer disposed between the plurality of integrated circuit die above the oxide layer.

10. The apparatus of claim 8, wherein the plurality of integrated circuit die are a first plurality of integrated circuit die, the wafer further comprising:
a device wafer comprising a second plurality of integrated circuit die that are bonded to respective die of the first plurality of integrated circuit die.

11. The apparatus of claim 8, wherein the non-elastic material layer comprises at least one of a metal layer or metal-alloy layer.

12. The apparatus of claim 8, further comprising:
alignment features positioned above the carrier wafer that identify locations where the plurality of integrated circuit die are to be bonded to the oxide layer.

13. The apparatus of claim 8, wherein the carrier wafer is to be de-bonded from the non-elastic material layer using light emitted from a laser source device, wherein the light is to pass through the carrier wafer in a direction from a first surface to a second surface of the carrier wafer, wherein the light to contact a first surface of the non-elastic material layer, wherein the non-elastic material layer to absorb the light.

14. The apparatus of claim 8, wherein the carrier wafer comprises at least one of glass or silicon.

15. A method comprising:
forming a metal layer on a carrier wafer;
forming an oxide layer on the metal layer; and
bonding a plurality of integrated circuit die on the oxide layer using an oxide to oxide fusion bonding operation that creates an oxide to oxide bond between the plurality of integrated circuit die and the oxide layer and forms a reconstructed wafer.

16. The method of claim 15, wherein the carrier wafer is a temporary wafer that is removed prior to dicing the plurality of integrated circuit die.

17. The method of claim 15, wherein the plurality of integrated circuit die are first plurality of integrated circuit die, the method further comprising:
bonding the reconstructed wafer to a device wafer comprising a second plurality of integrated circuit die, wherein the first plurality of integrated circuit die of the reconstructed wafer are bonded to respective die of the second plurality of integrated circuit die of the device wafer.

18. The method of claim 17, further comprising:
directing a laser source device to emit light that passes through the carrier wafer in a direction from a first surface to a second surface of the carrier wafer, the light directed to contact a first surface of the metal layer, wherein the metal layer absorbs the light and prevents the light from passing to the oxide layer.

19. The method of claim 15, further comprising:
forming alignment features above the carrier wafer that identify locations where the plurality of integrated circuit die are to be bonded to the oxide layer.

20. The method of claim 15, further comprising:
forming a dielectric layer above the plurality of integrated circuit die; and
performing a planarization operation to remove at least a portion of the dielectric layer and expose surfaces of the plurality of integrated circuit die.
